(19) United States
(12) Patent Application Publication
(10) Pub. No.: US 2026/0053076 A1
(43) Pub. Date: Feb. 19, 2026

(54) PACKAGE STRUCTURES AND METHODS OF FORMING THE SAME

(71) Applicant: TAIWAN SEMICONDUCTOR MANUFACTURING COMPANY, LTD., Hsinchu (TW)

(72) Inventors: Chuan-Cheng TSOU, Tainan (TW); Sung-Hsin YANG, Tainan (TW); Chen-Chieh CHIANG, Kaohsiung (TW); Hsu Tung YEN, Kaohsiung (TW); Kai-Cyuan YANG, Tainan (TW)

(21) Appl. No.: 18/948,589

(22) Filed: Nov. 15, 2024

Related U.S. Application Data
(60) Provisional application No. 63/684,400, filed on Aug. 18, 2024.

(51) Int. Cl. H01L 23/00

(52) U.S. Cl. CPC H01L 24/80; H01L 2224/80004; H01L 2224/8003; H01L 2224/80895; H01L 2224/80896

(57) ABSTRACT

Embodiments of the present disclosure relate to methods for forming a package structure. The method includes depositing a first layer on a front side of a wafer and a second layer on a backside of the wafer, depositing a third layer on the first layer and a fourth layer on the second layer, depositing an etch stop layer on the third layer, depositing a fifth layer on the etch stop layer and a sixth layer on the fourth layer, removing the fifth layer by a first process, and removing the etch stop layer by a second process.

### CROSS-REFERENCE TO RELATED APPLICATIONS

This application claims priority to U.S. Provisional Application Ser. No. 63/684,400 filed Aug. 18, 2024, which is incorporated by reference in its entirety.

### BACKGROUND

Semiconductor devices are used in a variety of electronic applications, such as personal computers, cell phones, digital cameras, and other electronic equipment, as examples. Semiconductor devices are typically fabricated by sequentially depositing various insulating or dielectric layers, conductive layers, and semiconductive layers of material over a semiconductor substrate, and patterning the various material layers using lithography to form circuit components and elements thereon. The semiconductor devices on a substrate are grouped to individual dies to achieve designed functions. In some cases, two or more substrates with different devices may be bonded together to form a complex substrate where each individual die includes two or more dies. For example, a substrate with logic devices may be bonded to a substrate with image sensors so that the logic devices are connected to the image sensors and each individual die may include a logic chip and an image sensor chip. The individual dies are singulated by sawing the integrated circuits along a scribe line. The individual dies are then packaged separately, in multi-chip modules, or in other types of packaging, for example.

The semiconductor industry continues to improve the integration density of various electronic components by continual reductions in minimum feature size, which allow more components to be integrated into a given area. These smaller electronic components require smaller and more advanced packaging systems than packages of the past, in some applications. Additionally, as more and more metal layers adding into the advanced BEOL (back end of line) processing, SOC (system on a chip) substrate warpage becomes higher and higher, which significantly degrades SoIC (system on integrated chips) chip-on-substrate process window and result in bond low yield.

Therefore, an improved package structure is needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, and 1F are schematic cross-sectional views of a package structure being fabricated, in accordance with some embodiments.

FIGS. 2A, 2B, 3A, 3B, 4A, and 4B are schematic side views of two device structures to be bonded, in accordance with some embodiments.

FIGS. 5A and 5B are schematic side views of a backside structure, in accordance with some embodiments.

FIGS. 6A and 6B are schematic side views of a device structure being fabricated, in accordance with some embodiments.

FIGS. 7A, 7B, 7C, 7D, and 7E are schematic side views of a package structure being fabricated, in accordance with some embodiments.

FIGS. 8A, 8B, and 8C schematically demonstrates warpage modulation, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure relate to methods for processing and bonding substrates to fabricate integrated circuit chips. The substrates may include semiconductor devices formed on front sides of the substrates and may be referred to as device substrates. Particularly, embodiments of the present disclosure provide a method for depositing a backside structure to protect devices on the substrate and/or to adjust substrate warpage during bonding and packaging. In some embodiments, the backside structure is deposited in a batch process chamber where the layers of the backside structure are formed on both the front side and the backside of the substrate. The layers formed on the backside of the substrate can reduce cavity defects.

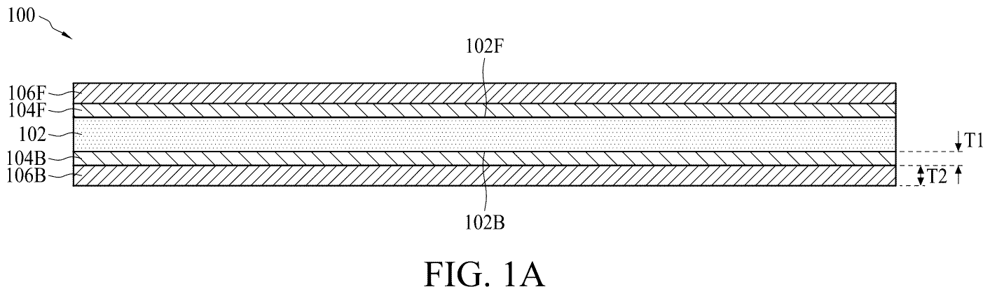

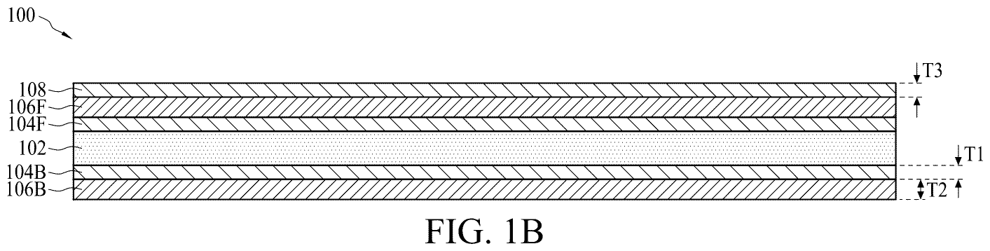

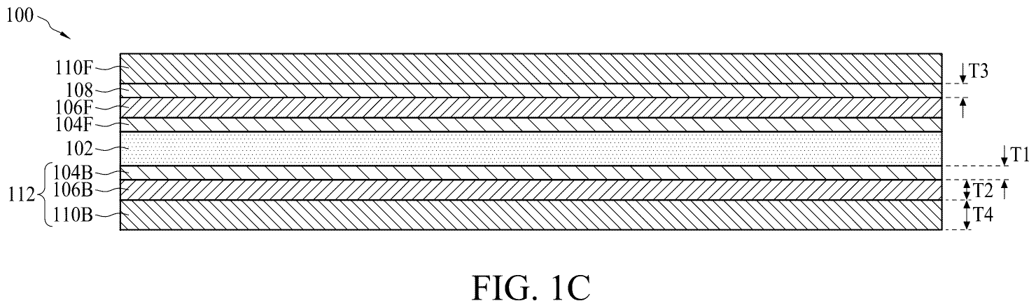

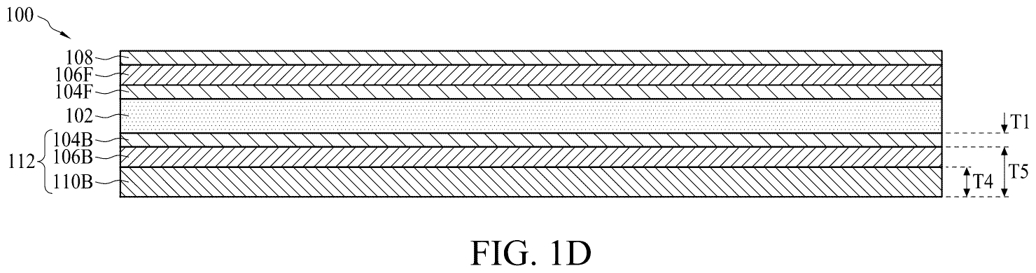

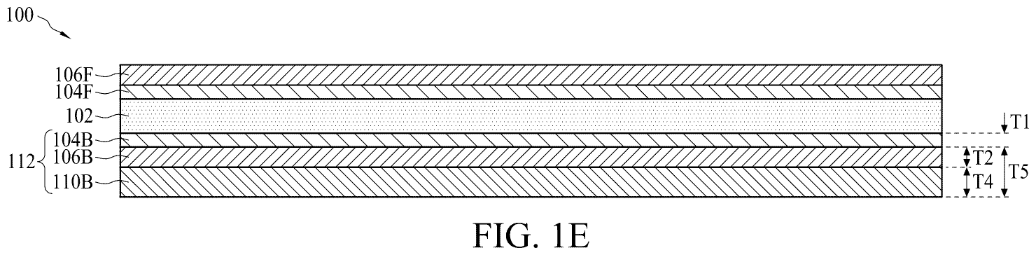

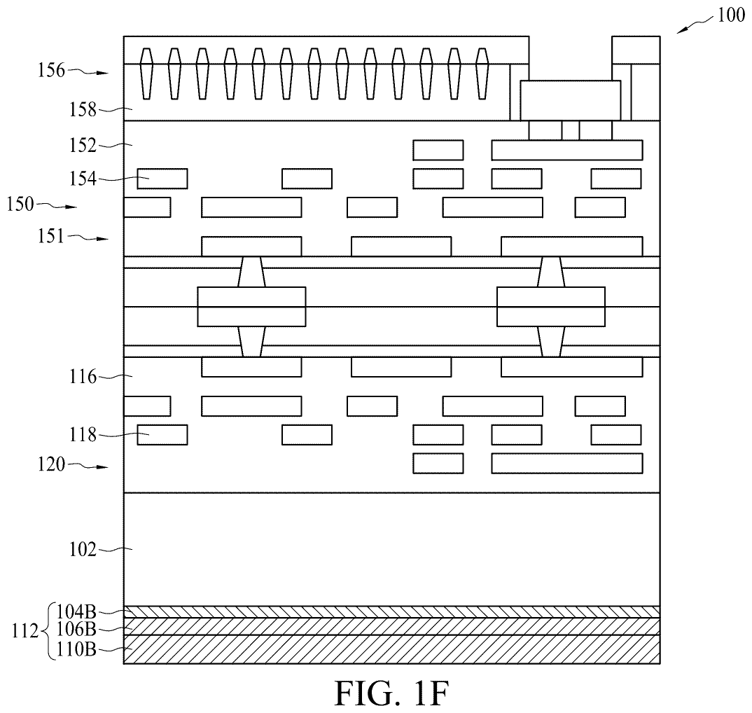

FIGS. 1A, 1B, 1C, 1D, 1E, and 1F are schematic cross-sectional views of a package structure 100 being fabricated according to embodiments of the present disclosure. As shown in FIG. 1A, front side and backside layers 104F, 104B are deposited on a front side 102F and a backside 102B of a wafer 102, respectively, and front side and backside layers 106F, 106B are deposited on the front side and backside layers 104F, 104B, respectively. In some embodiments, the wafer 102 is a blank wafer made of an elementary semiconductor, such as crystalline silicon or crystalline germanium; a compound semiconductor such as silicon carbide, gallium arsenide, gallium phosphide, indium phosphide, indium arsenide, and/or indium antimonide; an alloy semiconductor, such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), combinations thereof, or other suitable material. In some embodiments, the wafer 102 includes multi-layer semiconductors, semiconductor-on-insulator (SOI), for example silicon on insulator or germanium on insulator, and/or the like.

In some embodiments, the front side layer 104F and the backside layer 104B are formed simultaneously and have substantially the same properties, such as composition and thickness. For example, the front side layer 104F and the backside layer 104B are deposited simultaneously in a process chamber where both the front side 102F and the backside 102B of the wafer 102 are exposed to the processing environment. The front side and backside layers 104F, 104B may include any suitable dielectric material, such as an oxide, for example SiO, SiO₂, SINO, SiONC, or the like. In some embodiments, the front side and the backside layers 104F, 104B may include a semiconductor, such as SiGe, SiP, or the like. In some embodiments, when the wafer 102 is a silicon wafer, the front side dielectric layer 104F and the backside dielectric layer 104B each is made of or includes silicon oxide. In some embodiments, the front side and backside layers 104F, 104B may be deposited by any suitable process. In some embodiments, the front side and backside layers 104F, 104B are formed by flowing an oxidizing precursor to the process chamber. In some embodiments, one or more cleaning processes may be performed to remove native oxides and/or contaminations from the wafer 102 prior to forming the front side and backside layers 104F, 104B.

The front side layer 104F is sometimes referred to as a pad layer to be used in a subsequent patterning process. In some embodiments, the front side layer 104F and the backside layer 104B have the same or different thickness T1. In some embodiments, the thickness T1 is in a range between about 20 angstroms and about 2000 angstroms, such as from about 20 angstroms to about 60 angstroms.

In some embodiments, the front side layer 106F and the backside layer 106B are formed simultaneously and have substantially the same properties, such as composition and thickness. For example, the front side layer 106F and the backside layer 106B are formed simultaneously in a process chamber where both the front side dielectric layer 104F and the backside dielectric layer 104B are exposed to the processing environment. In some embodiments, the dielectric layers 104F, 104B, 106F, 106B are deposited in the same process chamber.

The front side and the backside layers 106F, 106B may include any suitable dielectric or semiconductor material, such as a nitride, for example, SiN, SiNO, Si₃N₄, SINC, SiONC, or the like. In some embodiments, the front side and the backside layers 106F, 106B may include a semiconductor, such as SiGe, SiP, or the like. The front side and the backside layers 106F, 106B include material different from the material of the front side and the backside layers 104F, 104B. In some embodiments, the front side layer 106F and the backside layer 106B each is made of or includes a nitride, such as silicon nitride. The front side and the backside layers 106F, 106B may be deposited by any suitable process. In some embodiments, the front side and the backside layers 106F, 106B are formed by flowing a nitrogen-containing precursor and a semiconductor-containing precursor to the process chamber. The front side layer 106F and the backside layer 106B have the same or different thickness T2. In some embodiments, the thickness T2 is in a range between about 100 angstroms and about 600 angstroms. The front side layer 106F may function as a hard mask layer during the subsequent patterning process. In some embodiments, the thickness T2 of the front side layer 106F is greater than the thickness T1 of the front side layer 104F. In some embodiments, a ratio R1 of the thickness T1 of the front side layer 104F to the thickness T2 of the front side layer 106F is between about one to one and about one to 18, such as between about one to nine and about one to 10.

While the front side layer 104F and the front side layer 106F are formed to enable subsequent FEOL processes, the backside layer 104B and the backside layer 106B remain on the backside 102B of the wafer 102 during wafer processing and may provide protection to the wafer 102. However, during certain processes, such as bonding process and wet clean process, the backside layers 104B, 106B that are formed simultaneously with the front side layers 104F, 106F, respectively, do not provide sufficient protection to the wafer 102, resulting in cracks or cavity defects in the wafer 102. Embodiments of the present disclosure provide an improved backside structure to prevent damaging the wafer 102 during wafer processing.

As shown in FIG. 1B, an etch stop layer 108 is deposited on the front side layer 106F. The etch stop layer 108 may be made of or include any suitable material having an etch selectivity different from that of the front side layer 106F. In some embodiments, the etch stop layer 108 includes the same material as the front side layer 104F. The etch stop layer 108 may have a thickness T3. In some embodiments, the thickness T3 is in a range between about 50 angstroms and about 1000 angstroms.

In some embodiments, the etch stop layer 108 is formed in a process chamber where the backside of the package structure 100 is not exposed to the processing environment. Thus, no material is formed on the backside layer 106B during the formation of the etch stop layer 108. The etch stop layer 108 may be formed by any suitable process, such as atomic layer deposition (ALD), plasma enhanced atomic layer deposition (PEALD), chemical vapor deposition (CVD), plasma enhanced chemical vapor deposition (PECVD), or a low-pressure chemical vapor deposition (LPCVD).

As shown in FIG. 1C, a front side layer 110F and a backside layer 110B are formed on the etch stop layer 108 and the backside layer 106B, respectively. Similar to the front side and the backside layers 104F, 104B and front side and the backside layers 106F, 106B, the front side layer 110F and the backside layer 110B are formed simultaneously and have substantially the same properties, such as composition and thickness. The front side layer 110F and the backside layer 110B are formed simultaneously in a process chamber where both the etch stop layer 108 and the backside layer 106B are exposed to the processing environment.

The backside layer 110B has a thickness T4. In some embodiments, the thickness T4 is in a range between about 100 angstroms and about 1600 angstroms. In some embodiments, the backside layer 110B includes the same material as the backside layer 106B, and the backside layer 110B and the backside dielectric layer 106B have a combined thickness T5. In some embodiments, the thickness T5 ranges from about 200 angstroms to about 20000 angstroms. The backside layers 106B, 110B having the thickness T5 can improve cavity defects during bonding process. Furthermore, in the embodiment where the backside layers 106B, 110B are made of silicon nitride, which induces more stresses and affects the warpage of the package structure 100. In some embodiments, a ratio R2 of the thickness T1 of the backside layer 104B to the combined thickness T5 of the backside layers 106F, 110F is between about one to 20 and about one to 60. The smaller ratio R2 compared to the ratio R1 (i.e., the greater thickness T5 compared to the thickness T2) can lead to improved cavity defects and stress and warpage tunning of the package structure 100.

As shown in FIG. 1C, the backside layer 110B, the backside layer 106B, and the backside layer 104B form a backside structure 112. The backside structure 112 may remain on the wafer 102 during wafer processing to protect the backside 102B of the wafer 102. In some embodiments, the backside structure 112 may also function as a stress modulation or warpage adjustment structure to achieve a certain warpage in the package structure 100.

As shown in FIG. 1D, the front side layer 110F is removed while the backside layer 110B remains. In some embodiments, the package structure 100 is placed into a process chamber in which the backside layer 110B is not exposed to the processing environment. The process chamber may be a dry etch chamber, such as a plasma etch chamber. In some embodiments, the front side layer 110F is removed by a plasma etch process utilizing a plasma source and an etchant. The plasma source may be an inductively coupled plasma (ICP) source, a transformer coupled plasma (TCP) source, an electron cyclotron resonance (ECR) source, a capacitively coupled plasma (CCP) source, or the like. In some embodiments, the etchant may include tetrafluoromethane (CF₄), difluoromethylene (CH₂F₂), or hexafluoroethane (C₂F₆), with optional addition of oxygen and/or nitrogen to control etch rate and etch selectivity. In some embodiments, the etchant has a high etch selectivity of the front side layer 110F over the etch stop layer 108. The etch stop layer 108 allows the front side layer 110F to be removed without damaging the front side layer 106F.

As shown in FIG. 1E, the etch stop layer 108 is removed. The etch stop layer 108 may be removed by any process that does not substantially affect the front side layer 106F. In some embodiments, a wet etch process is performed to remove the etch stop layer 108, while the front side layer 106F is not substantially affected by the wet etch process. In some embodiments, the wet etch process includes dilute HF dip.

In some embodiments, the package structure 100 includes the wafer 102, the front side layers 104F, 106F disposed on the front side 102F of the wafer 102, and the backside layers 104B, 106B, 110B disposed on the backside 102B of the wafer 102. In some embodiments, the front side layer 104F and the backside layer 104B each includes silicon oxide, and the front side layer 106F and the backside layers 106B, 110B each includes silicon nitride. The front side layers 104F, 106F may function as a mask structure during a patterning process. The backside layer 104B may function as a transition layer because the material of the backside layer 104B and the material of the wafer 102 have better lattice matching compared to the material of the backside layer 106B and the material of the wafer 102. The backside layers 106B, 110B may function as a protective layer to protect the wafer 102, such as to prevent cracks or cavity defects in the backside 102B of the wafer 102 due to the properties of the backside layers 106B, 110B and the combined thickness T5. If the backside layers 106B, 110B are formed directly on the backside 102B of the wafer 102 without the backside layer 104B, the backside layers 106B, 110B may be easily peeled off from the backside 102B of the wafer 102.

After the removal of the etch stop layer 108, FEOL processes are performed on the wafer 102 to form a plurality of devices (not shown), and back end of line (BEOL) processes may be performed to form an interconnect structure 120 over the wafer 102, as shown in FIG. 1F. In some embodiments, the plurality of devices includes a plurality of application specific integrated circuit (ASIC) devices. In some embodiments, the plurality of devices form a logic circuit, a memory circuit, a sensor circuit, or the like. In some embodiments, the plurality of devices form a control circuit for a sensor circuit. In some embodiments, the plurality of devices includes transistors, capacitors, diodes, resistors, or the like. In some embodiments, the devices are transistors, such as metal oxide semiconductor field effect transistors (MOSFETs), complementary metal oxide semiconductor (CMOS) transistors, bipolar junction transistors (BJTs), high voltage transistors, high frequency transistors, PFETs/NFETs, or other suitable transistors. The transistors may be planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels.

The interconnect structure 120 may be formed using BEOL fabrication techniques. The BEOL includes the formation and the patterning of dielectric layers and conductive metal layers. The interconnect structure 120 includes a plurality of conductive features 118, such as conductive lines and conductive vias, embedded in a dielectric structure 116.

As shown in FIG. 1F, the package structure 100 further includes a structure 150 bonded to the interconnect structure 120. In some embodiments, the structure 150 includes CMOS image sensor (CIS) devices. In some embodiments, the CIS devices are backside illuminated (BSI) CIS devices. For example, in some embodiments, the structure 150 includes an interconnect structure 151 and a wafer 158 disposed on the interconnect structure 151. The interconnect structure 151 includes dielectric layers 152 and conductive features 154 embedded in the dielectric layers 152. In some embodiments, a top surface of the interconnect structure 120 is configured to be bonded to a top surface of the interconnect structure 151 of the structure 150. A micro-lens array 156 may be formed on the wafer 158. Thus, in some embodiments, the wafer 102 is a logic circuit wafer including logic circuits, and the structure 150 is a sensor wafer having BSI sensing integrated circuits. The logic circuit wafer and the sensor wafer are bonded to form three-dimensional integrated circuits (3DICs).

The logic circuit wafer and the sensor wafer are bonded by any suitable process, such as direct bonding, hybrid bonding, or the like. During the bonding process, pressure may be applied to the package structure 100. The backside structure 112 protects the backside 102B of the wafer 102 during the bonding process. Furthermore, the backside structure 112 protects the wafer 102 from being damaged by the processing chemistry during wet etch process.

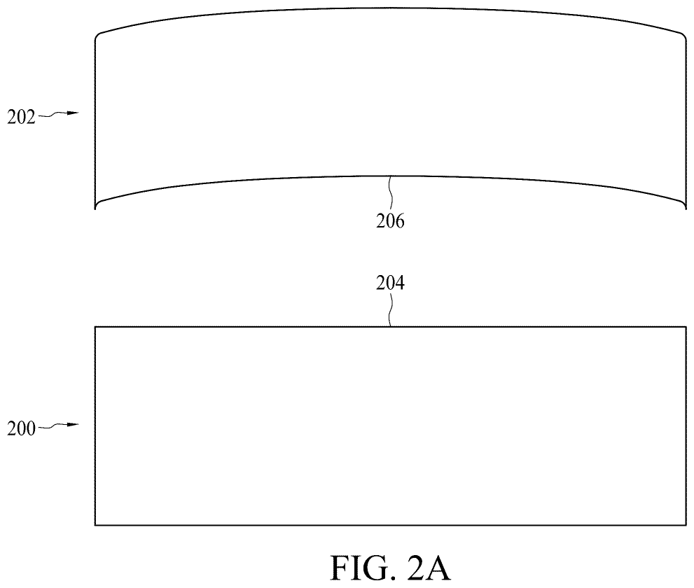

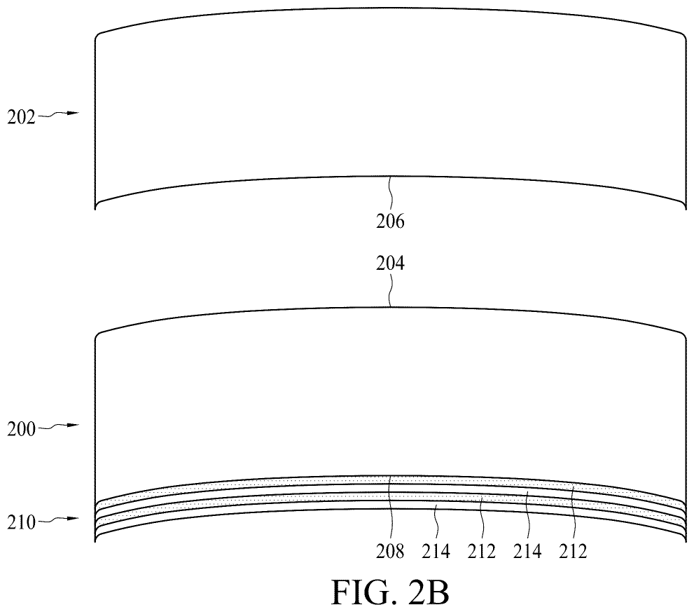

FIGS. 2A, 2B, 3A, 3B, 4A, and 4B are schematic side views of two device structures 200, 202 to be bonded, in accordance with some embodiments. As shown in FIG. 2A, the device structure 200 and the device structure 202 are to be bonded. In some embodiments, the device structures 200, 202 are wafers with devices and interconnect structures formed thereon. For example, the device structure 200 may include the wafer 102, the plurality of devices, and the interconnect structure 120 of FIG. 1F, and the device structure 202 includes the interconnect structure 151, the wafer 158, and the micro-lens array 156 of FIG. 1F. In some embodiments, the device structure 200 is a die, and the device structure 202 is a die. As shown in FIG. 2A, the device structure 200 has a bonding surface 204 that is to be bonded to a bonding surface 206 of the device structure 200. The bonding surface 204 may be the top surface of the topmost layer of the device structure 200. For example, the bonding surface 204 may be the top surface of the interconnect structure 120 (FIG. 1F). The bonding surface 206 may be the top surface of the topmost layer of the device structure 202. For example, the bonding surface 206 may be the top surface of the interconnect structure 151 (FIG. 1F). In some embodiments, the cross-sectional profile of the bonding surface 204 and the cross-sectional profile of the bonding surface 206 do not match. For example, as shown in FIG. 2A, the bonding surface 204 is substantially flat, and the bonding surface 206 is curved, such as having a concave cross-sectional profile.

In some embodiments, in order to change the cross-sectional profile of the bonding surface 204, a backside structure 210 is formed on a backside surface 208 of the device structure 200, as shown in FIG. 2B. The backside structure 210 includes at least one protective layer 212 and at least one buffer layer 214. In some embodiments, the protective layer 212 includes the same material as the backside layer 104B, and the buffer layer 214 includes the same material as the backside layer 106B. In some embodiments, two or more of the protective layers 212 and two or more of the buffer layers 214 are alternately stacked, as shown in FIG. 2B. As described above, the material of the protective layer 212 and the material of the wafer 102 have better lattice matching compared to the material of the buffer layer 214 and the material of the wafer 102. Furthermore, the protective layer 212 tends to induce a concave (smile shaped) warpage, and the buffer layer 214 tends to induce a convex (frown shaped) warpage. Thus, in some embodiments, the thickness of the buffer layer 214 is substantially greater than the thickness of the protective layer 212 in order to induce a concave warpage. As shown in FIG. 2B, after forming the backside structure 210 on the backside surface 208 of the device structure 200, the device structure 200 has a convex warpage, and the bonding surface 204 has a convex cross-sectional profile. The convex cross-sectional profile of the bonding surface 204 matches the concave cross-sectional profile of the bonding surface 206. As a result, the bonding process to bond the device structure 200 and the device structure 202 is improved.

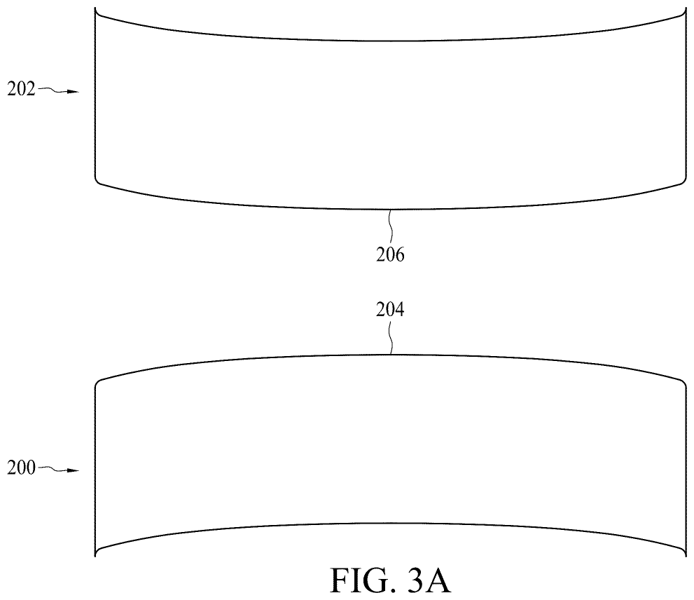

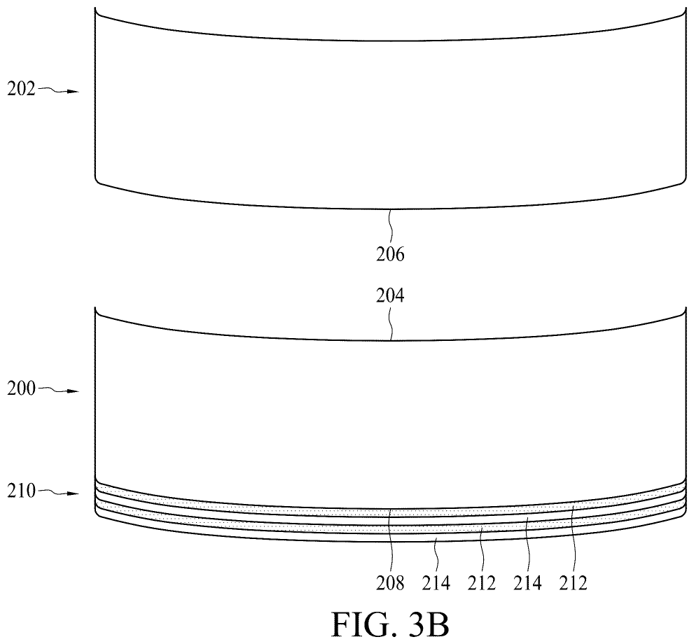

In some embodiments, as shown in FIG. 3A, the device structure 200 includes the bonding surface 204 that is curved, such as having a convex cross-sectional profile, and the device structure 202 includes the bonding surface 206 that is curved, such as having a convex cross-sectional profile. In some embodiments, the cross-sectional profile of the bonding surface 204 is changed by forming the backside structure 210 on the backside surface 208 of the device structure 200, as shown in FIG. 3B. As described above, the backside structure 210 includes alternating protective layers 212 and buffer layers 214. In some embodiments, the thickness of the protective layer 212 is greater than the thickness of the buffer layer 214, because the protective layer 212 tends to induce a concave warpage. Thus, with the backside structure 210 having thicker protective layers 212, the cross-sectional profile of the bonding surface 204 is changed from convex to concave, as shown in FIG. 3B. The concave profile of the bonding surface 204 matches the convex profile of the bonding surface 206, as shown in FIG. 3B.

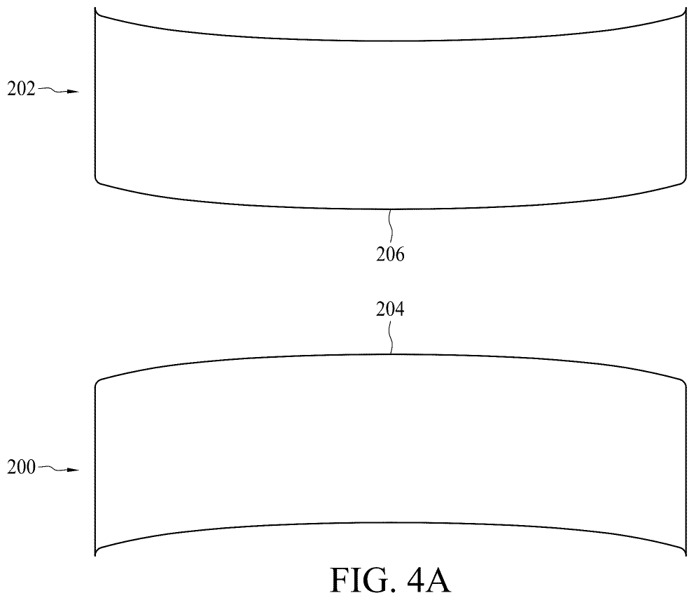

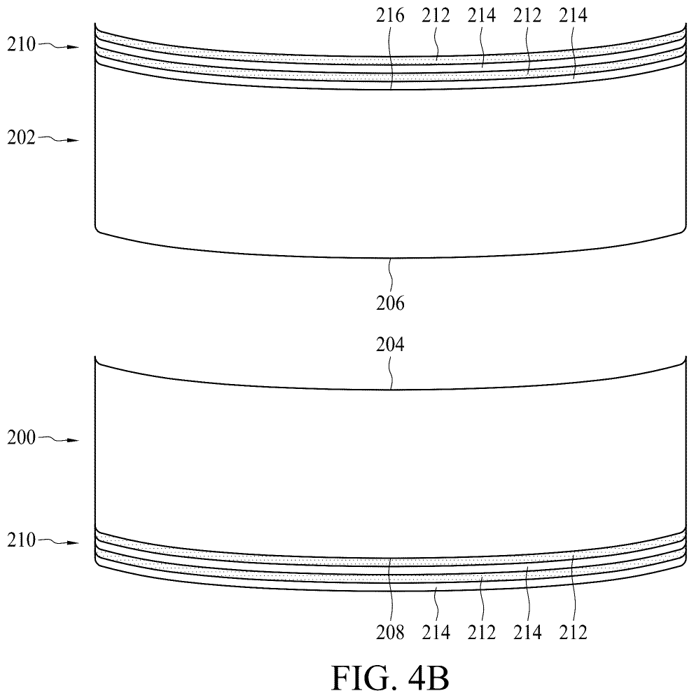

In some embodiments, as shown in FIG. 4A, the device structure 200 includes the bonding surface 204 that is curved, such as having a convex cross-sectional profile, and the device structure 202 includes the bonding surface 206 that is curved, such as having a convex cross-sectional profile. In some embodiments, the cross-sectional profiles of both the bonding surface 204 and the bonding surface 206 are changed by forming the backside structure 210 on the backside surface 208 of the device structure 200 and on the backside surface 216 of the device structure 202, as shown in FIG. 4B. As described above, the backside structure 210 includes alternating protective layers 212 and buffer layers 214. In some embodiments, the thickness of the protective layer 212 is greater than the thickness of the buffer layer 214, because the protective layer 212 tends to induce a concave warpage. Thus, with the backside structure 210 having thicker protective layers 212, the cross-sectional profile of the bonding surface 204 is changed from convex to concave, as shown in FIG. 4B. In some embodiments, the convex bonding surface 206 of the device structure 202 does not match the concave bonding surface 204 of the device structure 200. Thus, the backside structure 210 is formed on the backside surface 216 of the device structure 200 to change the degree of curvature of the bonding surface 206 of the device structure 200. In some embodiments, bonding surface 206 becomes more convex due to the addition of the backside structure 210, and the backside structure 210 includes protective layers 212 having greater thickness compared to the buffer layer 214. In some embodiments, bonding surface 206 becomes less convex due to the addition of the backside structure 210, and the backside structure 210 includes buffer layers 214 having greater thickness compared to the protective layer 212. By changing the cross-sectional profile of the bonding surface 204 from convex to concave and the cross-sectional profile of the bonding surface 206 from convex to more or less convex, the matching of the bonding surfaces 204, 206 is improved.

The backside structure 210 shown in FIGS. 2B, 3B, and 4B changes the warpage of the device structure 200 (and device structure 202 in FIG. 4B) in order to change the cross-sectional profile of the bonding surface 204 (and the bonding surface 206 in FIG. 4B), so the bonding surfaces 204, 206 are matched. Furthermore, the backside structure 210 protects the backside surface 208 of the device structure 200 (and the backside surface 216 of the device structure 202) during the bonding process, similar to the backside structure 112 protecting the wafer 102 as described in FIG. 1F.

The device structures 200, 202 may be any suitable structures. In some embodiments, the device structure 200 is a logic wafer, the device structure 202 is another logic wafer, and the bonding of the device structure 200 and the device structure 202 is a wafer-to-wafer bonding. In some embodiments, the device structure 200 is a die, the device structure 202 is a die, and the bonding of the device structure 200 and the device structure 202 is a die-to-die bonding. In some embodiments, the device structure 200 is a wafer, the device structure 202 is a die, and the bonding of the device structure 200 and the device structure 202 is a die-to-wafer bonding. The bonding of the device structures 200, 202 may form other types of package, such as chip-on-wafer-on-substrate (CoWoS) package, system-on-integrated-chips (SoIC) package, stacking memory devices package, or the like.

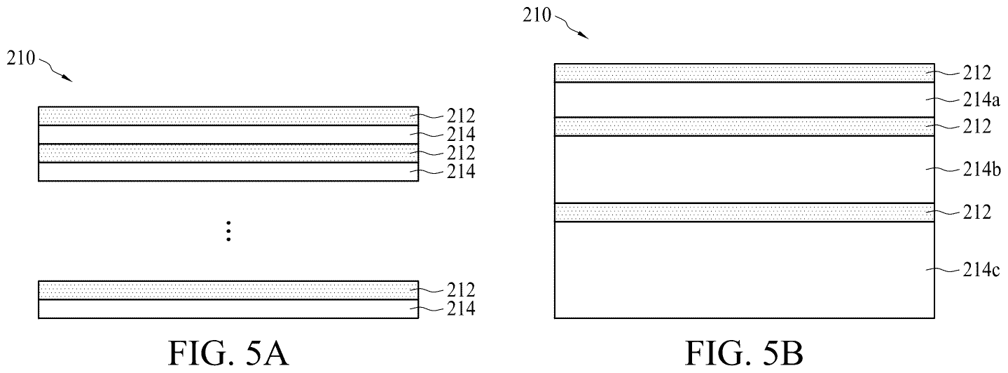

FIGS. 5A and 5B are schematic side views of the backside structure 210, in accordance with some embodiments. In some embodiments, the backside structure 210 includes alternating protective layers 212 and buffer layers 214, as shown in FIG. 5A. The number of the protective layer 212 may range from 1 to 50, and the number of the buffer layer 214 may range from 1 to 50. In some embodiments, the thickness of protective layers 212 is substantially constant, and the thickness of the buffer layers 214 is substantially constant. In some embodiments, the thickness of the protective layers 212 is substantially the same as the thickness of the buffer layers 214. In some embodiments, the thickness of the protective layers 212 is substantially different from the thickness of the buffer layers 214. As described above, in some embodiments, the thickness of the protective layers 212 is greater than the thickness of the buffer layers 214 in order to induce a concave warpage. In some embodiments, the thickness of the buffer layers 214 is greater than the thickness of the protective layers 212 in order to induce a convex warpage.

In some embodiments, the thickness of the buffer layers 214 is not constant, as shown in FIG. 5B. For example, the backside structure 210 includes the protective layers 212 and buffer layers 214a-c. The buffer layer 214a is the closest to the backside of a wafer (or a die) the backside structure 210 is formed thereon, and the buffer layer 214c is the farthest to the backside of the wafer (or the die). In some embodiments, the thickness of the buffer layer 214a-c increases in a direction away from the wafer. For example, the buffer layer 214a has a first thickness, the buffer layer 214b has a second thickness greater than the first thickness, and the buffer layer 214c has a third thickness greater than the second thickness. As described above, because of the lattice mismatch between the buffer layer 214 and the wafer, the protective layer 212 is formed between the buffer layer 214 and the wafer. In some embodiments, in order to induce a convex warpage of the wafer, the thickness of the buffer layer 214 is increased. If the thickness of the buffer layer 214 is greater than a threshold value, the buffer layer 214 may be peeled off easily. Thus, in order to accommodate a thick buffer layer 214, additional protective layers 212 are formed in the backside structure 210 to break up the thick buffer layer 214. As the buffer layer 214 gets farther away from the wafer, the risk of being peeled off decreases. Thus, the buffer layer 214 can have a greater thickness as it gets farther away from the wafer. Even though three protective layers 212 and three buffer layers 214a-c are shown in FIG. 5B, other numbers of the protective layers 212 and buffer layers 214a-c may be utilized. In some embodiments, the backside structure 210 includes alternating protective layers 212 and buffer layers 214, and the thickness of the buffer layers 214 increase in a direction away from a wafer (or a die) the backside structure 210 is formed thereon. The thickness of the protective layers 212 may remain substantially constant.

In some embodiments, the thickness of the protective layers 212 increases in a direction away from a wafer, while the thickness of the buffer layers 214 remains constant. In some embodiments, the buffer layers 214 provide protection to the wafer, and the protective layers 212 are softer than the buffer layers 214 and can provide cushion when the wafer is held by a substrate holder.

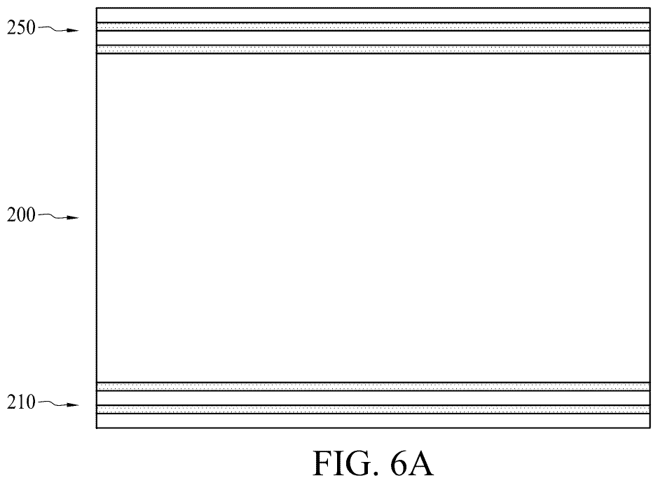

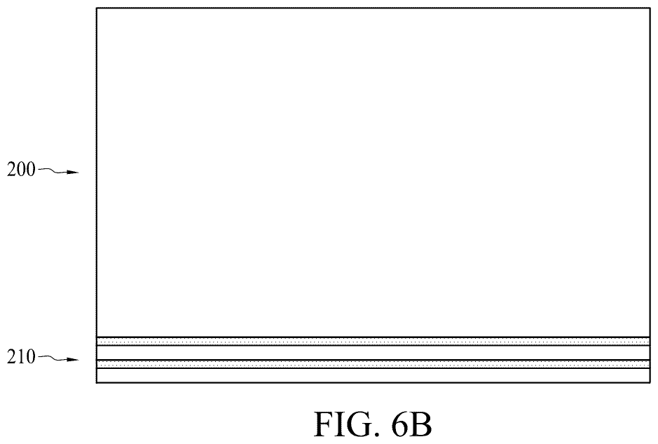

FIGS. 6A and 6B are schematic side views of the device structure 200 being fabricated, in accordance with some embodiments. In some embodiments, as shown in FIG. 6A, the device structure 200 is placed in a process chamber in which both the front side and the backside of the device structure 200 are exposed to the processing environment. Next, the backside structure 210 is formed on the backside of the device structure 200, and a front side structure 250 is formed on the front side of the device structure 200. In some embodiments, the backside structure 210 and the front side structure 250 are formed simultaneously. The layers of the backside structure 210 are formed sequentially, and the layers of the front side structure 250 are formed sequentially simultaneously with corresponding layers of the backside structure 210. As the front side structure 250 and the backside structure 210 are formed on the device structure 200 simultaneously, the warpage of the device structure 200 is not affected because the front side structure 250 and the backside structure 210 are formed on both the front side and the backside of the device structure 200, respectively.

Next, as shown in FIG. 6B, the front side structure 250 is removed. The device structure 200 with the front side structure 250 and the backside structure 210 may be placed in an etch chamber in which the backside structure 210 is not exposed to the processing environment. The layers of the front side structure 250 may be removed by one or more etch processes. The etch processes may be dry etch processes, wet etch processes, or combinations thereof. After the removal of the front side structure 250, the warpage (or the lack of) of the device structure 200 is modulated to better match the warpage of another device structure, such as the device structure 202, to be bonded to the device structure 200.

In some embodiments, the device structure 200 is a blank wafer or a blank carrier wafer. The backside structure 210 can modulate the warpage of the blank wafer so after the components are formed or bonded on the blank wafer, the warpage can match a warpage of a device to be bonded to the components on the blank wafer.

In some embodiments, the backside structure 210 is formed in a process chamber in which the backside of the device structure 200 is exposed to the processing environment, while the front side of the device structure 200 is not exposed to the processing environment. The backside structure 210 is then formed on the backside of the device structure 200, and the front side structure 250 is not formed on the front side of the device structure 200.

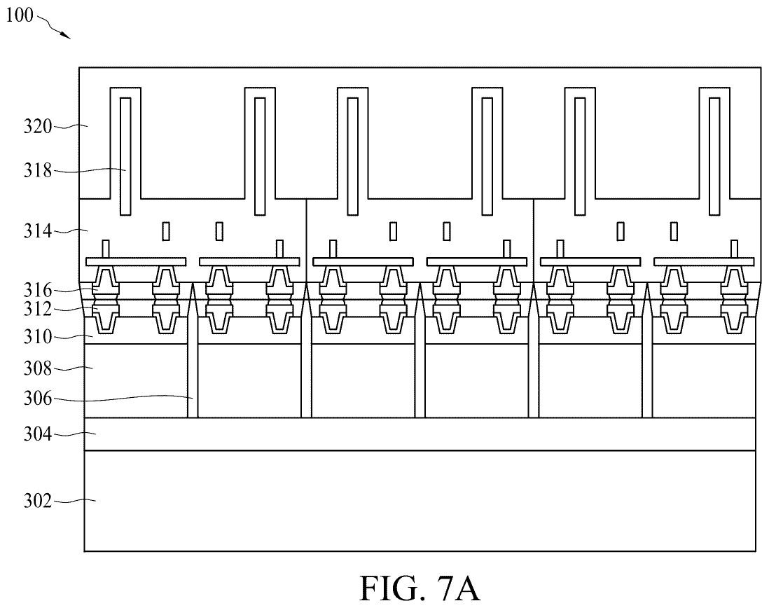

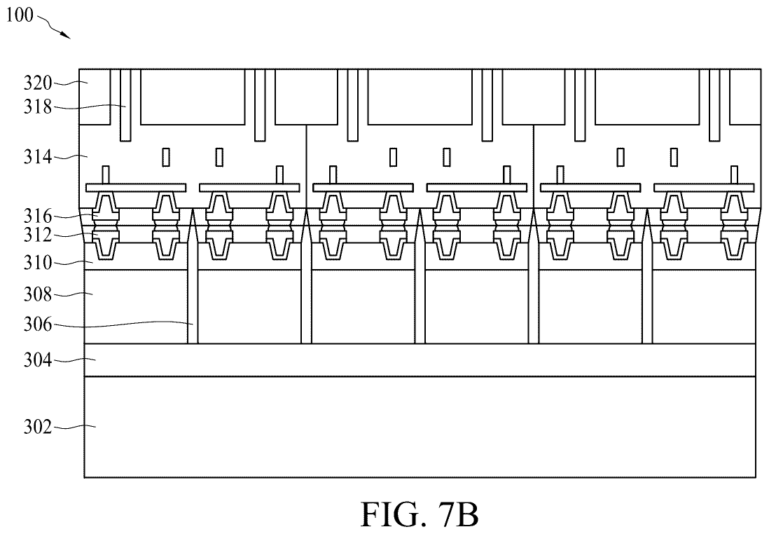

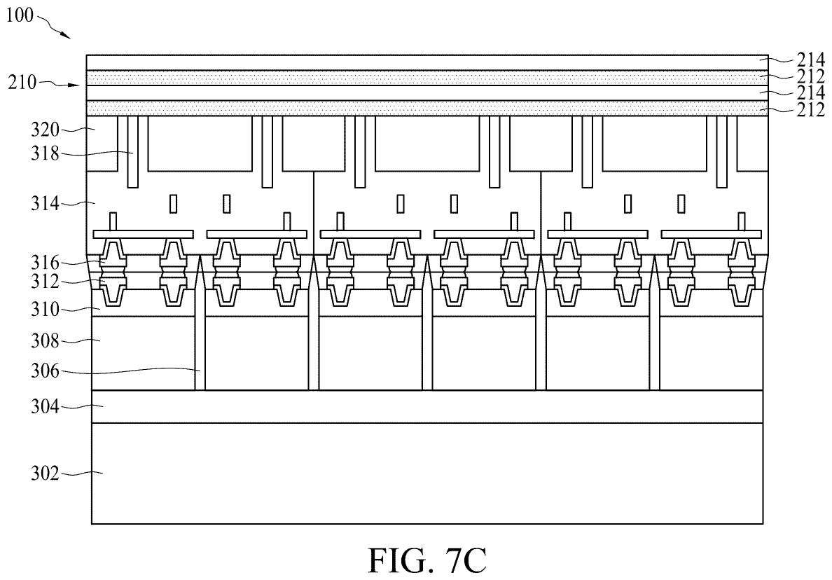

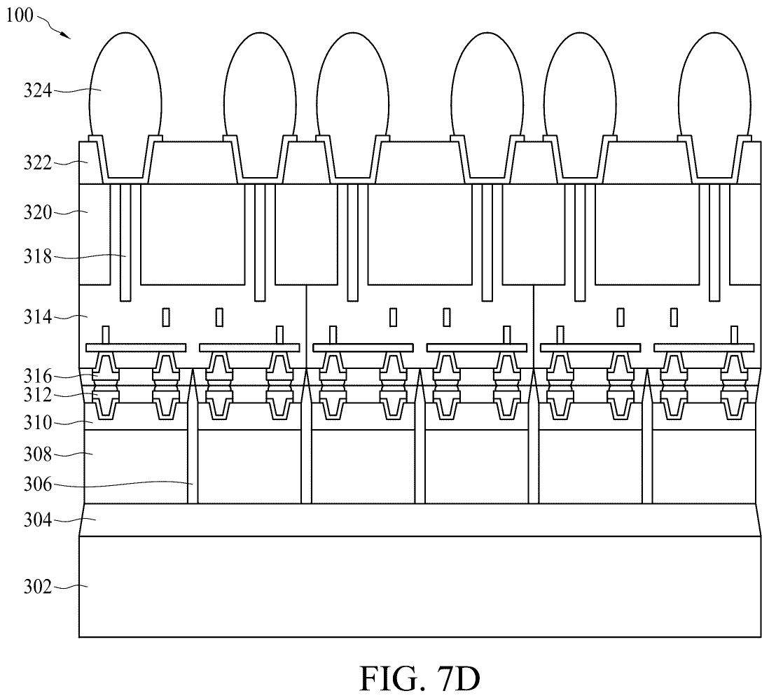

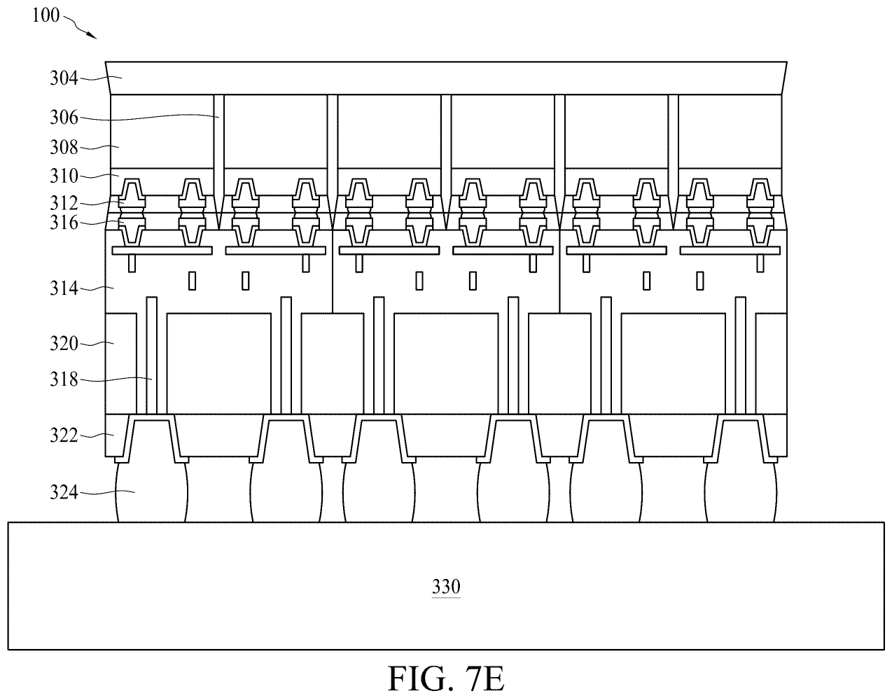

FIGS. 7A, 7B, 7C, 7D, and 7E are schematic side views of the package structure 100 being fabricated, in accordance with some embodiments. In some embodiments, as shown in FIG. 7A, the package structure 100 is a CoWoS package. The package structure 100 includes a carrier 302, an adhesive layer 304 is disposed on the carrier 302, and a plurality of dies 308 are disposed over the adhesion layer 304. The dies 308 may be any suitable dies, such as integrated circuit dies. The dies 308 may be separated by a dielectric material 306. The dielectric material 306 may be any suitable dielectric material. In some embodiments, the dielectric material 306 is a molding material that encapsulate the dies 308. An interconnect structure 310 is disposed over the dies 308. The interconnect structure 310 includes conductive features 312 formed in one or more dielectric layers. The interconnect structure 310 is bonded to an interconnect structure 314. The interconnect structure 314 may include conductive features electrically connected to the conductive features 312 of the interconnect structure 310. The interconnect structures 310, 314 may be bonded by any suitable process, such as direct bonding or hybrid bonding. An interposer substrate 320 is disposed over the interconnect structure 314, and a plurality of vias 318 are formed in the interposer substrate 320. In some embodiments, the vias 318 are through substrate vias. The interposer substrate 320 and the interconnect structure 314 may be formed separately from the dies 308 and the interconnect structure 310. Similarly, the dies 308 and the interconnect structures 310 may be formed over the carrier 302 before being bonded to the interconnect structure 314 and the interposer substrate 320.

As shown in FIG. 7B, the interposer substrate 320 is thinned down to expose the vias 318. The interposer substrate 320 may be thinned down by a grinding, lapping, etching, polishing, other suitable process, or combinations thereof. Next, as shown in FIG. 7C, the backside structure 210 is formed on the interposer substrate 320. The backside structure 210 may include alternating protective layers 212 and buffer layers 214, as shown in FIG. 7C. In some embodiments, the interposer substrate 320 is a silicon substrate, and the protective layer 212 is formed on the interposer substrate 320 due to better lattice matching. As described above, the thickness of the buffer layers 214 may be different, such as increasing in a direction away from the interposer substrate 320. In some embodiments, the thickness of the buffer layers 214 is greater than the thickness of the protective layers 212 in order to induce a convex warpage of the interposer substrate 320. In some embodiments, the thickness of the protective layers 212 is greater than the thickness of the buffer layers 214 in order to induce a concave warpage of the interposer substrate 320.

In some embodiments, as shown in FIG. 7D, the backside structure 210 is removed, while the interposer substrate 320 maintains the warpage that is the result of having the backside structure 210. In other words, once the backside structure 210 forms a warpage on the interposer substrate 320, the removal of the backside structure 210 would not affect the warpage. A dielectric material 322 is deposited over the interposer substrate 320, and electrical connectors 324 are formed in the dielectric material 322. The dielectric material 322 may include any suitable dielectric material. In some embodiments, the dielectric material 322 includes a polymer, such as polyimide. The electrical connectors 324 are electrically connected to corresponding vias 318. The electrical connectors 324 may be solder balls, metal pillars, controlled collapse chip connection (C4) bumps, micro bumps, electroless nickel-electroless palladium-immersion gold technique (ENEPIG) formed bumps, or the like. The electrical connectors 324 may be formed by commonly used methods such as evaporation, electroplating, printing, solder transfer, ball placement, or the like.

In some embodiments, the backside structure 210 is not removed, and the electrical connectors 324 are formed in the backside structure 210. For example, the electrical connectors 324 extend through the protective layers 212 and the buffer layers 214 of the backside structure 210 to be electrically connected to the vias 318.

As shown in FIG. 7E, the package structure 100 is flipped over and attached to a printed circuit board (PCB) 330, and the carrier 302 is removed. The carrier 302 may be removed by any suitable process. In some embodiments, the carrier 302 is removed using a release film (not shown). In some embodiments, the adhesion layer 304 remains over the dies 308, as shown in FIG. 7E. The electrical connectors 324 are electrically connected to the PCB 330. In some embodiments, the interposer substrate 320 has a concave warpage as a result of having the backside structure 210 formed thereon. The concave warpage of the interposer substrate 320 improves contacts between the electrical connectors 324 and the PCB 330.

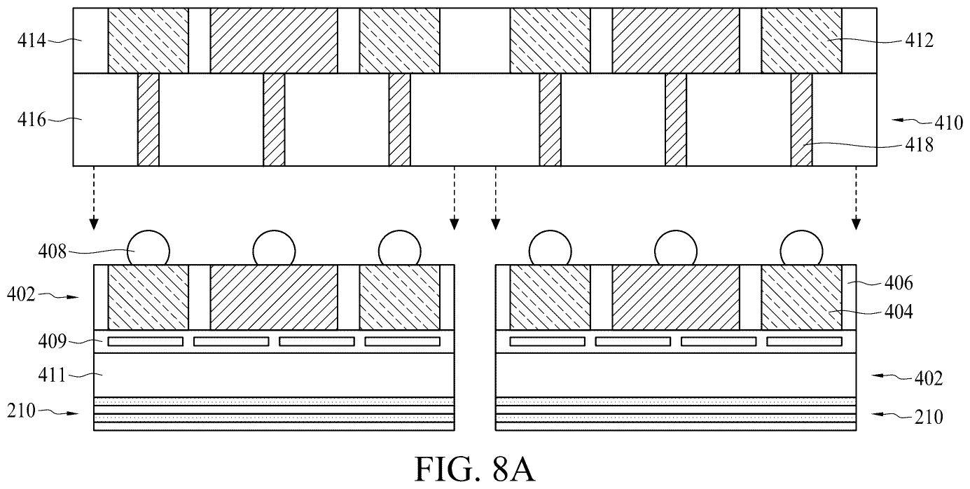

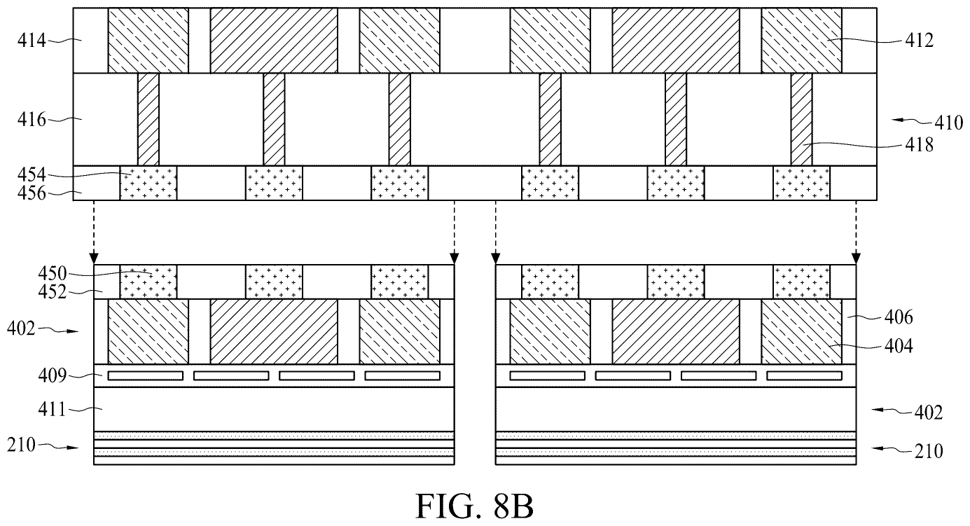

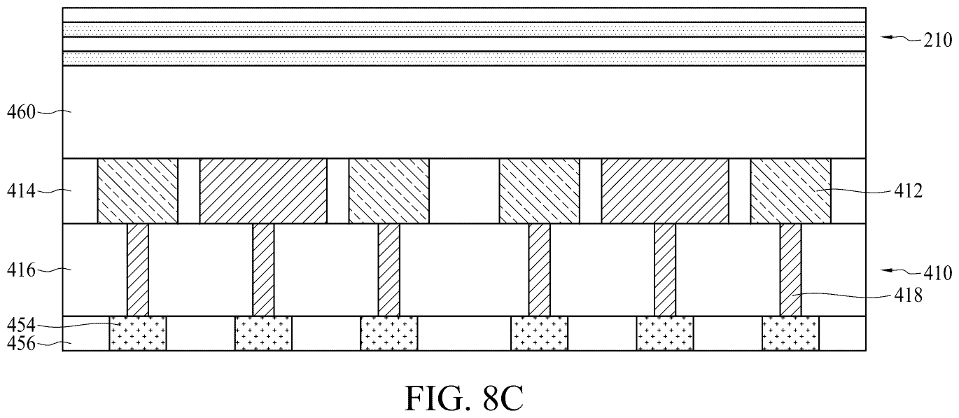

FIGS. 8A, 8B, and 8C schematically demonstrates warpage modulation, in accordance with some embodiments. As shown in FIG. 8A, first dies 402 are to be bonded to a second die 410. In some embodiments, each of the first dies 402 includes circuit layers 404 electrically isolated by an isolation layer 406. In some embodiments, the circuit layers 404 includes a plurality of devices, such as the plurality of devices described in FIG. 1F. The isolation layer 406 may include any suitable dielectric material. A plurality of electrical connectors 408 are disposed over the circuit layers 404, as shown in FIG. 1F. An interconnect structure 409 may be disposed below the circuit layers 404 and the isolation layer 406. The interconnect structure 409 is placed on a carrier 411, and the backside structure 210 is formed on the backside of the carrier 411, as shown in FIG. 8A. The backside structure 210 can form a warpage on the carrier 411 and the materials disposed thereon. In some embodiments, a concave warpage is formed, which causes the electrical connectors 408 to be better connected to the second die 410.

As shown in FIG. 8A, the second die 410 includes circuit layers 412 electrically isolated by an isolation layer 414. An interposer substrate 416 is disposed below the circuit layers 412 and the isolation layer 414, and a plurality of vias 418 are formed in the interposer substrate 416. The vias 418 may be electrically connected to corresponding circuit layers 412. The first dies 402 and the second die 410 are bonded so the electrical connectors 408 are electrically connected to corresponding vias 418.

As shown in FIG. 8B, instead of using the electrical connectors 408, the first dies 402 are bonded to the second die 410 using dielectric layers 452, 456 including conductive features 450, 454, respectively. In some embodiments, the dielectric layer 452 is formed on each first die 402, and the conductive features 450 are formed in the dielectric layer 452. The backside structure 210 can provide a curved top surface of the dielectric layer 452, so the top surface of the dielectric layer 452 can have a better match with a bottom surface of the dielectric layer 456. The dielectric layer 456 and the conductive features 454 are disposed below the interposer substrate 416. In some embodiments, each via 418 is electrically connected to a corresponding conductive feature 454, as shown in FIG. 8B. The backside structure 210 may be used in a similar way as the backside structure 210 described in FIGS. 2B and 3B.

In some embodiments, the cross-sectional profile of the bottom surface of the dielectric layer 456 may be changed by the backside structure 210, as shown in FIG. 8C. In some embodiments, a carrier 460 is formed over the circuit layers 412 and the isolation layer 414, and the backside structure 210 is formed on the carrier 460. The backside structure 210 can change the cross-sectional profile of the bottom surface of the dielectric layer 456 so the bottom surface of the dielectric layer 456 can better match with the top surface of the dielectric layer 452 of the first dies 402 (FIG. 8B). The backside structure 210 and the carrier 460 may be removed after the first dies 402 are bonded to the second die 410. The backside structures 210 may be used in a similar way as the backside structures 210 described in FIG. 4B.

The package shown in FIGS. 8A to 8C may be a system on integrated chips (SoIC) package. The backside structure 210 form a warpage in one or more dies (or changes the cross-sectional profile of the top and/or bottom surfaces that are to be bonded) to improve the bonding process and the bonding of the dies. The backside structure 210 may be used in other types of packages.

The present disclosure in various embodiments provides a method to form a package structure 100. In some embodiments, the method includes forming a backside structure 210 on a backside of a device structure 200. The backside structure 210 includes alternating protective layers 212 and buffer layers 214. Some embodiments may achieve advantages. For example, the protective layers 212 tend to induce a concave warpage on the device structure 200, and the buffer layers 214 tend to induce a convex warpage on the device structure 200. By modulating the warpage of the device structure 200, the bonding of the device structure 200 to another device structure is improved.

An embodiment is a method. The method includes depositing a first layer on a front side of a wafer and a second layer on a backside of the wafer, depositing a third layer on the first layer and a fourth layer on the second layer, depositing an etch stop layer on the third layer, depositing a fifth layer on the etch stop layer and a sixth layer on the fourth layer, removing the fifth layer by a first process, and removing the etch stop layer by a second process.

Another embodiment is a method. The methods includes providing a first device structure, the first device structure has a first surface and a second surface opposite the first surface, and the second surface has a first cross-sectional profile. The method further includes depositing a first structure on the first surface, and the first structure causes the second surface to have a second cross-sectional profile different from the first cross-sectional profile. The method further includes bonding the first device structure to a second device structure.

A further embodiment is a method. The method includes bonding an interposer substrate to one or more dies, removing a portion of the interposer substrate to expose one or more vias, and depositing a structure on the interposer substrate and the vias. The depositing of the structure includes depositing a first protective layer on the interposer substrate and the vias, depositing a first buffer layer on the first protective layer, depositing a second protective layer on the first buffer layer, and depositing a second buffer layer on the second protective layer. The method further includes removing the structure, depositing a dielectric material on the interposer substrate and the vias, and forming one or more electrical connectors in the dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
depositing a first layer on a front side of a wafer and a second layer on a backside of the wafer;
depositing a third layer on the first layer and a fourth layer on the second layer;
depositing an etch stop layer on the third layer;
depositing a fifth layer on the etch stop layer and a sixth layer on the fourth layer;
removing the fifth layer by a first process; and
removing the etch stop layer by a second process.

2. The method of claim 1, wherein the first and second layers each comprises an oxide, and the third and fourth layers each comprises a nitride.

3. The method of claim 2, wherein the sixth layer comprises a same material as the fourth layer.

4. The method of claim 3, wherein the first layer has a first thickness, the second layer has a second thickness, the third layer has a third thickness, and the fourth and sixth layer together has a fourth thickness.

5. The method of claim 4, wherein the fourth thickness is greater than the second thickness.

6. The method of claim 4, wherein a first ratio of the first thickness to the third thickness is less than a second ratio of the second thickness to the fourth thickness.

7. The method of claim 6, wherein the first ratio is between one to one and one to 18, and the second ratio is between one to 20 and one to 60.

8. The method of claim 1, wherein the first process is a dry etch process.

9. The method of claim 8, wherein the second process is a wet etch process.

10. A method, comprising:
providing a first device structure, wherein the first device structure has a first surface and a second surface opposite the first surface, and the second surface has a first cross-sectional profile;
depositing a first structure on the first surface, wherein the first structure causes the second surface to have a second cross-sectional profile different from the first cross-sectional profile; and
bonding the first device structure to a second device structure.

11. The method of claim 10, wherein the first structure comprises alternating protective layers and buffer layers.

12. The method of claim 11, wherein the protective layers comprise oxide layers, and buffer layers comprise nitride layers.

13. The method of claim 12, wherein a thickness of the buffer layers increases in a direction away from the first surface.

14. The method of claim 12, wherein a thickness of the buffer layers is greater than a thickness of the protective layers, the first cross-sectional profile is flat, and the second cross-sectional profile is convex.

15. The method of claim 12, wherein a thickness of the buffer layers is less than a thickness of the protective layers, the first cross-sectional profile is convex, and the second cross-sectional profile is concave.

16. The method of claim 10, further comprising depositing a second structure on a surface of the second device structure opposite a bonding surface of the second device structure, wherein a cross-sectional profile of the bonding surface is changed by the second structure.

17. A method, comprising:
bonding an interposer substrate to one or more dies;
removing a portion of the interposer substrate to expose one or more vias;
depositing a structure on the interposer substrate and the vias, comprising:
depositing a first protective layer on the interposer substrate and the vias;
depositing a first buffer layer on the first protective layer;
depositing a second protective layer on the first buffer layer; and
depositing a second buffer layer on the second protective layer;
removing the structure;
depositing a dielectric material on the interposer substrate and the vias; and
forming one or more electrical connectors in the dielectric material.

18. The method of claim 17, wherein a thickness of the first buffer layer is greater than a thickness of the first protective layer.

19. The method of claim 17, wherein a thickness of the second buffer layer is greater than a thickness of the first buffer layer.

20. The method of claim 19, wherein a thickness of the first protective layer is the same as a thickness of the second protective layer.
